(19) United States
(12) Patent Application Publication
(10) Pub. No.: US 2022/0263305 A1
(43) Pub. Date: Aug. 18, 2022

(54) CIRCUIT STRUCTURE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Taiji YANAGIDA, Mie (JP); Hiroki SHIMODA, Mie (JP); Kazuya KOMAKI, Mie (JP); Ayaka ASANO, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/622,076

(22) PCT Filed: Jun. 5, 2020
(86) PCT No.: PCT/JP2020/022288

§ 371 Date: Dec. 22, 2021

(30) Foreign Application Priority Data
Jun. 26, 2019 (JP) 2019-119080

(51) Int. Cl. H02G 5/10; H05K 7/20

(52) U.S. Cl. CPC H02G 5/10; H05K 7/2039

(57) ABSTRACT

Provided is a circuit structure having a novel structure that allows heat from a heat-generating component to be dissipated more efficiently. A circuit structure includes: heat-generating components that generate heat when energized; energization bus bars that are connected to connection portions of the heat-generating components; and heat transfer portions that are provided in the energization bus bars and that are in heat-conductive contact with a heat-dissipating body, wherein the heat transfer portions are in heat-conductive contact with the heat-generating components.

### TECHNICAL FIELD

The present disclosure relates to a circuit structure that includes a heat-generating component.

### BACKGROUND ART

Conventionally, there are cases in which a heat-dissipating structure for dissipating heat from a heat-generating component is provided in a circuit structure including a heat-generating component such as a relay or fuse that generates heat when energized. For example, a structure in which heat from a relay that is housed inside a case is dissipated using an intermediate portion of a bus bar that connects a connection portion of the relay and a connection terminal of a battery that is arranged outside the case is proposed in Patent Document 1. Specifically, a structure is disclosed in which the intermediate portion of the bus bar, which is extended to the outside of the case housing the relay, is brought into contact with a chassis, a housing that houses an entire power supply device, or the like via an insulative heat conduction sheet, whereby heat generated by the relay is conducted to the chassis or the housing and dissipated.

### CITATION LIST

### Patent Documents

Patent Document 1: JP 2014-79093A

### SUMMARY OF INVENTION

### Technical Problem

However, in the structure disclosed in Patent Document 1, since the heat-dissipating structure is provided in the intermediate portion of the bus bar, which forms an energization portion connecting the relay and the battery, an increase in the distance between the connection portion of the relay and the heat-dissipating portion is unavoidable. Due to this, there is an inherent problem in which heat generated by the relay is not dissipated efficiently.

In view of this, the present disclosure aims to provide a circuit structure having a novel structure that allows heat from a heat-generating component to be dissipated more efficiently.

### Solution to Problem

A circuit structure according to the present disclosure is a circuit structure including: a heat-generating component that generates heat when energized; an energization bus bar that is connected to a connection portion of the heat-generating component; and a heat transfer portion that is provided in the energization bus bar and that is in heat-conductive contact with a heat-dissipating body, wherein the heat transfer portion is in heat-conductive contact with the heat-generating component.

### Advantageous Effects of Invention

According to the present disclosure, a circuit structure that allows heat from a heat-generating component to be dissipated more efficiently can be provided.

### BRIEF DESCRIPTION OF DRAWINGS

FIG. 1 is an exploded perspective view describing a representative example of a configuration of a circuit structure according to embodiment 1.

FIG. 2 is a front view of the circuit structure illustrated in FIG. 1 in an assembled state.

FIG. 3 is an exploded perspective view in which the circuit structure illustrated in FIG. 1 is broken up further into individual constituent components.

FIG. 4 is a perspective view in which the circuit structure in the assembled state illustrated in FIG. 2 is viewed from below, and is an exploded view in which only second heat-conducting members are separated.

FIG. 5 is an exploded perspective view describing representative constituent components relating to a relay illustrated in FIG. 3.

FIG. 6 is an enlarged view of a cross-section taken along line VI-VI in FIG. 2.

FIG. 7 is an exploded perspective view describing representative constituent components relating to the relay in a circuit structure according to embodiment 2.

FIG. 8 is a diagram according to embodiment 2 that corresponds to FIG. 6.

### DESCRIPTION OF EMBODIMENTS

### Description of Embodiments of Present Disclosure

First, aspects of the present disclosure will be listed and described.

A circuit structure according to the present disclosure is

(1) a circuit structure including: a heat-generating component that generates heat when energized; an energization bus bar that is connected to a connection portion of the heat-generating component; and a heat transfer portion that is provided in the energization bus bar and that is in heat-conductive contact with a heat-dissipating body, wherein the heat transfer portion is in heat-conductive contact with the heat-generating component.

In the circuit structure according to the present disclosure, an energization bus bar that is connected to a connection portion of a heat-generating component includes a heat transfer portion that is in heat-conductive contact with a heat-dissipating body, and this heat transfer portion is in heat-conductive contact with the heat-generating component as a result of being superposed on and coming into contact with the heat-generating component itself either directly or via another heat-conducting member. Thus, the heat transfer portion of the energization bus bar can be brought into direct heat-conductive contact with the heat-generating component, which is a heat source, and the heat transfer portion can be brought into heat-conductive contact with the heat-dissipating body at a position closest to the heat-generating component. Consequently, heat from a heat-generating component can be dissipated more efficiently compared to a conventional structure in which a bus bar is extended in a direction away from a heat-generating component and brought into contact with a heat-dissipating body.

Moreover, the heat transfer portion of the energization bus bar need not be provided so as to extend over a long distance from the connection portion of the energization bus bar, and can simply be interposed between the heat-generating component and the heat-dissipating body. Thus, the heat transfer portion can be arranged efficiently in an existing space, and the size and cost of the circuit structure can also be reduced.

In addition, heat from the heat-generating component can be dissipated in an excellent manner using a compact structure without incurring an increase in the number of components because it suffices to simply provide, to an existing energization bus bar, a heat transfer portion that comes into heat-conductive contact with the heat-generating component and the heat-dissipating body.

Note that heat-generating components include components that generate heat when energized, such as a relay, a fuse, and a current sensor. As the structure for connecting the energization bus bar to the connection portion of the heat-generating component, any connection structure, such as a bolted structure, may be adopted.

(2) Preferably, the energization bus bar includes a bolt fastening portion that is bolted to the connection portion, and a bolt insertion hole provided in the bolt fastening portion includes a tolerance-absorbing space that absorbs the tolerance of the heat-generating component and allows the heat transfer portion to come into contact with the heat-generating component.

Since the bolt insertion hole in the energization bus bar includes a tolerance-absorbing space that absorbs the tolerance of the heat-generating component, a difference in the state of contact of the heat transfer portion of the energization bus bar with the heat-generating component occurring due to the tolerance of the heat-generating component can be reduced or avoided. Consequently, the heat transfer portion can be reliably brought into contact with the heat-generating component, and heat from the heat-generating component can be dissipated stably.

(3) Preferably, the heat-generating component includes two or more heat-generating parts, and the heat transfer portion is in heat-conductive contact with the heat-generating component on sides thereof corresponding to the two or more heat-generating parts.

This is preferable because heat from the heat-generating component can be dissipated efficiently with few components as a result of the heat transfer portion being in heat-conductive contact with the heat-generating component on sides thereof where the plurality of heat-generating parts of the heat-generating component are provided. Note that, if the heat-generating component includes three or more heat-generating parts, a configuration may be adopted such that the heat transfer portion is in heat-conductive contact with the heat-generating component on all sides thereof where the heat-generating parts are provided, or such that the heat transfer portion is in heat-conductive contact with the heat-generating component only on sides thereof where two of the heat-generating parts are provided.

(4) In (1) or (2) above, preferably, the heat-generating component includes two or more heat-generating parts, and the heat transfer portion is in heat-conductive contact with the heat-generating component on at least one side thereof corresponding to at least one of the two or more heat-generating parts and is separated from the heat-generating component on sides corresponding to the rest of the heat-generating parts.

For example, depending on the heat-generating part, it may be unnecessary to dissipate heat from the heat-generating part via the heat transfer portion of the energization bus bar, and a sufficient heat dissipation effect may be obtained by transferring the heat from the heat-generating part via another nearby part. In such a case, heat from one heat-generating part can be transferred to the heat transfer portion more efficiently by separating the heat transfer portion of the energization bus bar from the other heat-generating part which does not require the dissipation of heat via the heat transfer portion. Consequently, heat from the heat-generating component can be dissipated more efficiently.

Note that, as the structure for separating the heat transfer portion from the other heat-generating part, any structure may be adopted, such as a structure in which the bus bar is bent and provided with a step portion, or a structure in which another member having low heat conductivity is interposed between the other heat-generating part and the heat transfer portion.

(5) Preferably, a case that houses the energization bus bar and the heat-generating component is included, one surface of the heat transfer portion is in heat-conductive contact with the heat-generating component, and the other surface of the heat transfer portion is in heat-conductive contact with the case, which is the heat-dissipating body.

By bringing the other side of the heat transfer portion into heat-conductive contact with the case housing the energization bus bar and the heat-generating component, the case can be used as a heat-dissipating body, and heat dissipation can be improved by the transfer of heat being promoted to a further extent.

(6) In (5) above, preferably, a first heat-conducting member that is interposed between contact surfaces of the heat-generating component and the case is included, and the first heat-conducting member is positioned relative to the contact part of the case that comes into contact with the heat transfer portion. This is preferable because the transfer of heat from the heat transfer portion of the energization bus bar to the case can be promoted. Moreover, since the first heat-conducting member is positioned relative to the contact part of the case that comes in contact with the heat transfer portion, the transfer of heat in the heat transfer portion can be promoted even more stably.

(7) In (5) or (6) above, preferably, the contact part of the case that comes into contact with the heat transfer portion is in heat-conductive contact with another member that is the heat-dissipating body on an outer surface side, a second heat-conducting member that is interposed between contact surfaces of the other member and the outer surface side of the case is included, and the second heat-conducting member is positioned relative to the contact part on the outer surface side of the case. This is preferable because the dissipation of heat from the heat-generating component to the other member via the energization bus bar and the thinned contact part of the case can be promoted even more favorably.

Note that the positioning of the second heat-conducting member relative to the contact part on the outer surface side of the case may be realized by a protrusion, a level difference, or the like provided in the case or may be realized by a protrusion, a recess, or the like provided in another member that is fixedly placed on the case.

(8) In any of (5) to (7) above, preferably, the contact part of the case that comes into contact with the heat transfer portion is thinner than the vicinity of the contact part in the case. By forming the contact part of the case that comes in contact with the heat transfer portion so as to be thinner than the vicinity thereof in the case, heat can be transferred to the outside via the contact part of the case more favorably. Thus, heat from the heat-generating component can be dissipated more favorably in a case such as where the case is installed to a heat-dissipating body having higher heat dissipation performance than the case does.

(9) In (6) above, preferably, the contact part of the case that comes into contact with the heat transfer portion is thinner than the vicinity of the contact part in the case, and the first heat-conducting member is positioned relative to the contact part by a level difference that is formed at a boundary between the contact part and the vicinity. The level difference formed at the boundary between the contact part and the vicinity thereof due to the contact part being thin can be used to position the first heat-conducting member. Thus, efficient dissipation of heat from the heat-generating component can be realized stably with few components.

(10) In (7) above, preferably, the contact part of the case that comes into contact with the heat transfer portion is thinner than the vicinity of the contact part in the case, and the second heat-conducting member is positioned relative to the contact part by a level difference that is formed at a boundary between the contact part and the vicinity. The level difference formed at the boundary between the contact part and the vicinity thereof due to the contact part being thin can be used to position the second heat-conducting member. Thus, efficient dissipation of heat from the heat-generating component can be realized stably with few components. In particular, heat can be dissipated even more efficiently and stability can be ensured by adopting this configuration in combination with (9).

### Details of Embodiments of Present Disclosure

Specific examples of the circuit structure according to the present disclosure will be described with reference to the drawings below. Note that the present disclosure is not limited to these examples, and is intended to include all modifications that are indicated by the claims and are within the meaning and scope of equivalents of the claims.

### Embodiment 1

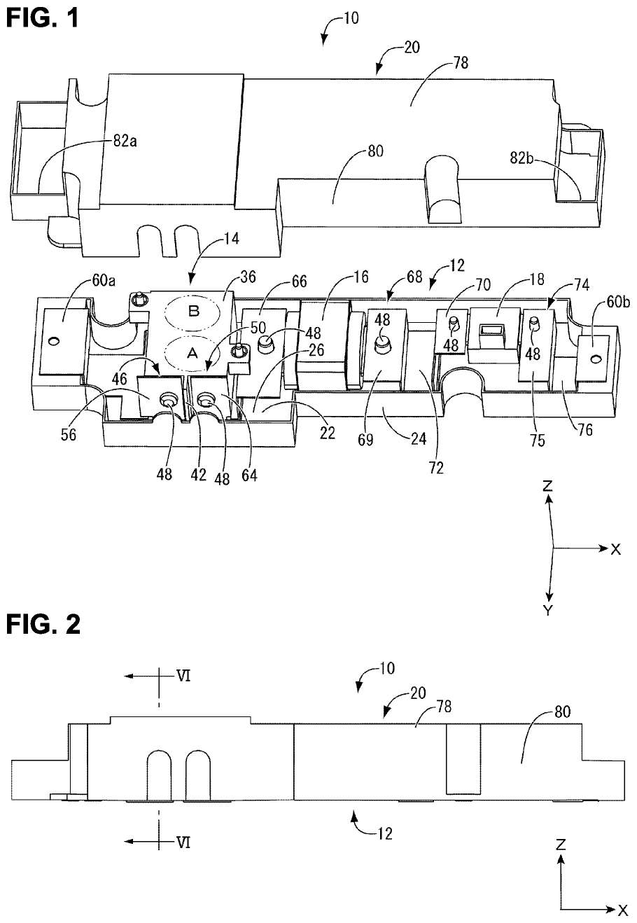

Embodiment 1, in which the technique disclosed in the present description is applied to a circuit structure 10, will be described with reference to FIGS. 1 to 6. The circuit structure 10 is installed in a vehicle (not shown) such as an electric automobile or a hybrid automobile, for example, and supplies and controls electric power from a power source (not shown) such as a battery to a load (not shown) such as a motor. While the circuit structure 10 can be oriented in any direction, in the following description, the Z direction is regarded as the upward direction, the Y direction is regarded as the forward direction, and the X direction is regarded as the rightward direction. Furthermore, when more than one of the same member is provided, the reference numeral therefor may be provided to only some of the members and may be omitted for the rest.

As illustrated in FIG. 1, the circuit structure 10 includes a base member 12 that constitutes a case, electric components disposed in the base member 12, such as a relay 14 (one example of a heat-generating component), a fuse 16 (one example of a heat-generating component), and a current sensor 18 (one example of a heat-generating component), and a lid member 20 that covers the base member 12 from above and constitutes the case.

### Base Member 12

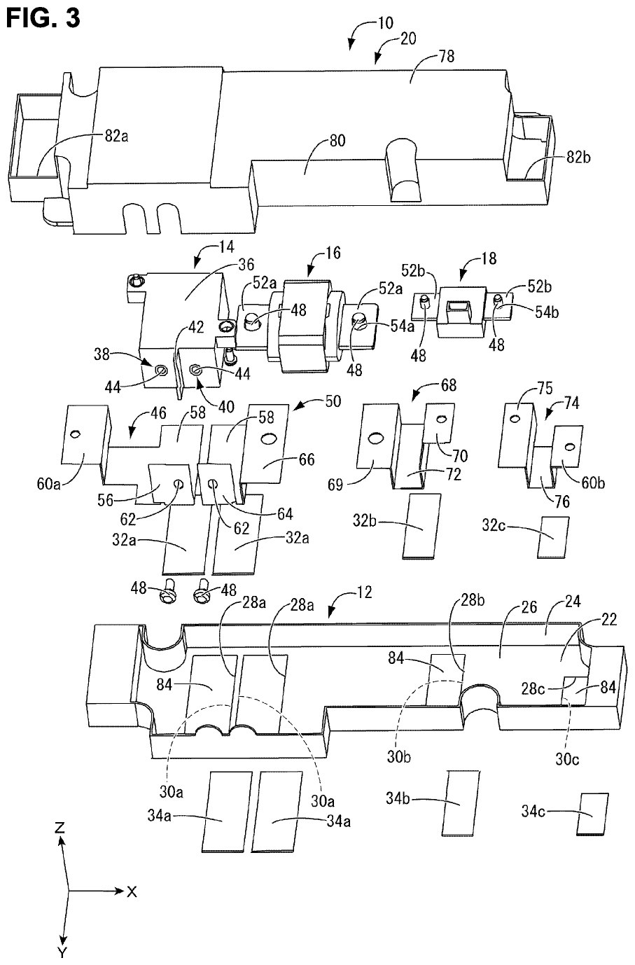

The base member 12 is obtained by injection molding an insulative synthetic resin into a predetermined shape. The synthetic resin forming the base member 12 may contain a filler such as glass fibers. As illustrated in FIG. 3 for example, the base member 12 has a substantially rectangular box shape as a whole that is open upward, and includes a bottom wall 22 and a peripheral wall 24 that stands upright from the end edge portion of the bottom wall 22. In embodiment 1 of the present disclosure, the base member 12 has a substantially rectangular outer shape when seen from above. Note that the outer shape of the base member 12 is not limited to that in the present embodiment.

As illustrated in FIG. 3, in the left end portion of an upper surface 26 of the bottom wall 22 of the base member 12, two first-heat-conducting-member-housing portions 28a that have a recessed shape, have a rectangular shape in a plan view, and are open upward are disposed adjacent to one another in the left-right direction and disposed side by side across a slight gap. Also, in the center portion of the upper surface 26, a first-heat-conducting-member-housing portion 28b that is provided with a smaller area than the first-heat-conducting-member-housing portions 28a, has a recessed shape, and has a rectangular shape in a plan view is formed open upward. Furthermore, in the right end portion of the upper surface 26, a rectangular first-heat-conducting-member-housing portion 28c that is provided with a smaller area than the first-heat-conducting-member-housing portion 28b, has a recessed shape, and has a rectangular shape in a plan view is formed open upward.

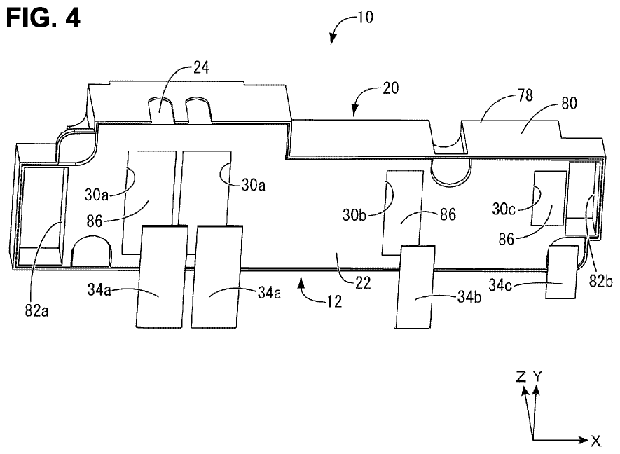

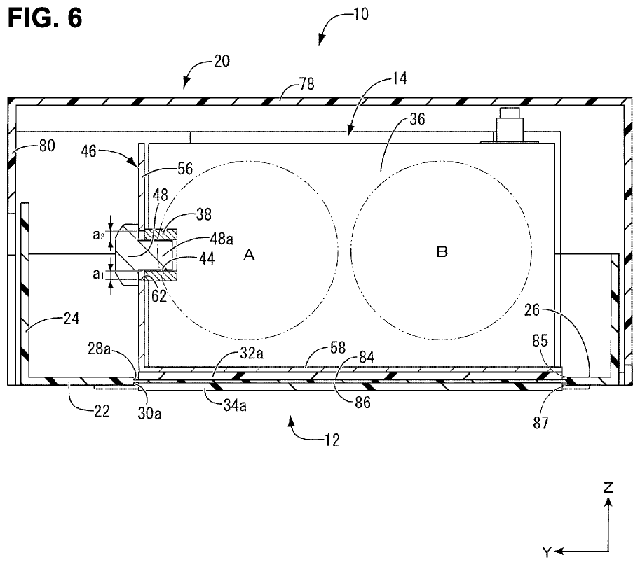

In addition, as illustrated in FIG. 4, on the reverse side of the first-heat-conducting-member-housing portions 28a in the bottom wall 22 of the base member 12, second-heat-conducting-member-housing portions 30a that have a recessed shape and that have a rectangular shape in a rear view are formed open downward at the same positions as the first-heat-conducting-member-housing portions 28a in the top-bottom direction. Similarly, second-heat-conducting-member-housing portions 30b, 30c that have a recessed shape and that have a rectangular shape in a rear view are formed open downward at the same positions as the first-heat-conducting-member housing portions 28b, 28c in the top-bottom direction on the reverse side of the first-heat-conducting-member-housing portions 28b, 28c. As illustrated in FIG. 6, in the bottom wall 22 of the base member 12, parts forming bottom surfaces 84, 86 of the recessed first-heat-conducting-member-housing portions 28a, 28b, 28c and the recessed second-heat-conducting-member-housing portions 30a, 30b, 30c are formed thinner than the vicinity thereof.

### First Heat-Conducting Members 32a, 32b, 32c and Second Heat-Conducting Members 34a, 34b, 34c

As illustrated in FIGS. 3 and 6, first heat-conducting members 32a are housed in the first-heat-conducting-member-housing portions 28a, and second heat-conducting members 34a are housed in the second-heat-conducting-member-housing portions 30a. Similarly, first heat-conducting members 32b, 32c are housed in the first-heat-conducting-member-housing portions 28b, 28c, and second heat-conducting members 34b, 34c are housed in the second-heat-conducting-member-housing portions 30b, 30c.

Each of the first heat-conducting members 32a, 32b, 32c and the second heat-conducting members 34a, 34b, 34c is insulative, is formed in the shape of a sheet that is flat in the top-bottom direction, and is made of a synthetic resin that has higher heat conductivity than air. Specifically, a silicone resin, a non-silicone acrylic or ceramic resin, or the like can be used. More specifically, examples include heat-conductive silicone rubber, heat-conductive grease, heat-dissipating gap fillers, etc., made from silicone resins. The first heat-conducting members 32a, 32b, 32c are flexible, and the thickness thereof can change in response to a force applied thereto in the top-bottom direction. Note that, while each of the first heat-conducting members 32a, 32b, 32c and the second heat-conducting members 34a, 34b, 34c are formed in the shape of a sheet in the present embodiment, there is no limitation to this and any shape may be adopted.

### Relay 14

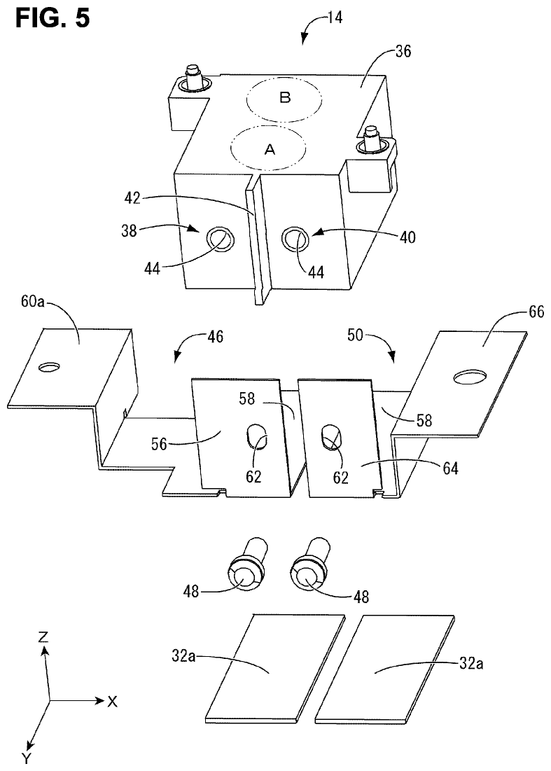

As illustrated in FIGS. 3 and 5, the relay 14 is a mechanical electric component, so to speak, and includes, inside a rectangular solid-shaped main body 36, an unshown contact portion and excitation coil portion. On the front surface of the main body 36, a first power terminal 38 (one example of a connection portion) that is provided on the left side and a second power terminal 40 (one example of a connection portion) that is provided on the right side are disposed side by side in the left-right direction. When a current flows between the first power terminal 38 and the second power terminal 40, heat is generated by the contact portion and the excitation coil portion. The contact portion is provided on the side (the front side in FIG. 5) close to the first power terminal 38 and the second power terminal 40, and the excitation coil portion is provided on the side (the back side in FIG. 5) distant from the first power terminal 38 and the second power terminal 40. The relay 14, which is a heat-generating component, includes two heat-generating parts, namely a heat-generating part A formed by the contact portion housed inside the main body 36 and a heat-generating part B formed by the excitation coil portion housed inside the main body 36. Furthermore, on the front surface of the main body 36, an insulating plate 42 that partitions the first power terminal 38 and the second power terminal 40 from one another is provided between the two terminals 38, 40. Note that, as illustrated in FIG. 5, a bolt hole 44 that extends in the front-rear direction is formed in each of the first power terminal 38 and the second power terminal 40.

A later-described first bus bar 46 (one example of an energization bus bar) is connected to the first power terminal 38 by screwing a bolt 48 into the corresponding bolt hole 44. Also, a later-described second bus bar 50 (one example of an energization bus bar) is connected to the second power terminal 40 by screwing a bolt 48 into the corresponding bolt hole 44.

### Fuse 16

As illustrated in FIG. 3, the fuse 16 is formed in the shape of a rectangular solid. A lead terminal 52a (one example of a connection portion) is formed protruding outward in the left-right direction from each of the left and right side surfaces of the fuse 16. The lead terminals 52a are made from a metal plate. Each lead terminal 52a is provided with an insertion hole 54a that penetrates the lead terminal 52a in the top-bottom direction.

### Current Sensor 18

As also illustrated in FIG. 3, the current sensor 18 is formed in the shape of a rectangular solid. A lead terminal 52b (one example of a connection portion) is formed protruding outward in the left-right direction from each of the left and right side surfaces of the current sensor 18. The lead terminals 52b are made from a metal plate. Each lead terminal 52b is provided with an insertion hole 54b that penetrates the lead terminal 52b in the top-bottom direction.

### First Bus Bar 46

The first bus bar 46 is obtained by pressing a metal plate into a predetermined shape. As the metal forming the first bus bar 46, a metal that has high thermal conductivity and low electrical resistance, such as copper, a copper alloy, aluminum, or an aluminum alloy, can be chosen, as appropriate. As illustrated in FIG. 3, the first bus bar 46 extends in the left-right direction, and is formed so as to bend in a crank shape at an appropriate position in the left-right direction. The first bus bar 46 includes: a first bolt fastening portion 56 that is provided in the right end portion and that constitutes a bolt fastening portion; a heat transfer portion 58 that extends toward the rear from the bottom end portion of the first bolt fastening portion 56; and an external connection portion 60a that extends toward the left from the heat transfer portion 58 in a crank shape and that is provided in the left end portion. That is, the first bolt fastening portion 56 and the external connection portion 60a are connected and integrated by the heat transfer portion 58.

The first bolt fastening portion 56 has a rectangular shape when seen from the front, and has a bolt insertion hole 62 having a vertically elongated elliptic shape penetrating therethrough slightly to the right of the center portion thereof. The first bolt fastening portion 56 is bolted to the first power terminal 38 as a result of a bolt 48 being inserted through the bolt insertion hole 62 and being screwed into the bolt hole 44 of the first power terminal 38 in a state in which the first bolt fastening portion 56 is superposed on the first power terminal 38 from the front. Thus, the first bolt fastening portion 56 and the relay 14 are electrically connected.

Since the bolt insertion hole 62 provided in the first bolt fastening portion 56 has a vertically elongated elliptical shape, a top-bottom direction tolerance of the relay 14 relative to the first bolt fastening portion 56 can be absorbed. That is, as illustrated in FIG. 6, the bolt insertion hole 62 has tolerance-absorbing spaces (a₁ and a₂ in FIG. 6) above and below a screw portion 48a of the bolt 48. Thus, the heat transfer portion 58 extending from the bottom end portion of the first bolt fastening portion 56 can reliably come into contact with the bottom surface of the main body 36 of the relay 14 as described later.

Furthermore, when an unshown external circuit terminal is bolted to the external connection portion 60a in a state in which the external circuit terminal is superposed on the external connection portion 60a, the external connection portion 60a and the external circuit terminal are electrically connected.

### Second Bus Bar 50

The second bus bar 50 is obtained by pressing a plate made from a desired metal, examples of which have been described in connection with the first bus bar 46, into a predetermined shape. As illustrated in FIG. 3, the second bus bar 50 extends in the left-right direction, and is formed so as to bend in a crank shape at an appropriate position in the left-right direction. The second bus bar 50 includes: a second bolt fastening portion 64 that is provided in the left end portion and that constitutes a bolt fastening portion; a heat transfer portion 58 that extends toward the rear from the bottom end portion of the second bolt fastening portion 64; and a fuse connection portion 66 that extends upward from the heat transfer portion 58 in an inverse L shape and that is provided in the right end portion. That is, the second bolt fastening portion 64 and the fuse connection portion 66 are connected and integrated by the heat transfer portion 58. As in the first bus bar 46, a bolt insertion hole 62 having tolerance-absorbing spaces (a₁ and a₂ in FIG. 6) is also formed in the second bolt fastening portion 64.

The fuse connection portion 66 has a rectangular shape when seen from above. The fuse connection portion 66 is fixed to a lead terminal 52a that protrudes toward the left from the fuse 16 by a bolt 48 in a state in which the fuse connection portion 66 is superposed on the lead terminal 52a. Thus, the second bus bar 50 and the fuse 16 are electrically connected.

### Third Bus Bar 68

As illustrated in FIG. 3, a third bus bar 68 that is an energization bus bar extends in the left-right direction, and is formed so as to bend in a crank shape at an appropriate position in the left-right direction. The third bus bar 68 includes a fuse connection portion 69 that is provided in the left end portion, a current sensor connection portion 70 that is provided in the right end portion, and a U-shaped portion that connects the fuse connection portion 69 and the current sensor connection portion 70 in a U shape. A heat transfer portion 72 is formed by the bottom wall of the U-shaped portion. The third bus bar 68 is also made of a desired metal having high thermal conductivity and low electric resistance, examples of which have been described in connection with the first bus bar 46.

The fuse connection portion 69 is fixed to a lead terminal 52a that protrudes toward the right from the fuse 16 by screwing a bolt 48 in a state in which the fuse connection portion 69 is superposed on the lead terminal 52a. Thus, the third bus bar 68 and the fuse 16 are electrically connected.

The current sensor connection portion 70 is fixed to a lead terminal 52b that protrudes toward the left from the current sensor 18 by screwing a bolt 48 in a state in which the current sensor connection portion 70 is superposed on the lead terminal 52b. Thus, the third bus bar 68 and the current sensor 18 are electrically connected.

### Fourth Bus Bar 74

As illustrated in FIG. 3, a fourth bus bar 74 that is an energization bus bar extends in the left-right direction, and is formed so as to bend in a crank shape at an appropriate position in the left-right direction. The fourth bus bar 74 includes a current sensor connection portion 75 that is provided in the left end portion, an external connection portion 60b that is provided in the right end portion, and a U-shaped portion that connects the current sensor connection portion 75 and the external connection portion 60b in a U shape. A heat transfer portion 76 is formed by the bottom wall of the U-shaped portion. The fourth bus bar 74 is also made of a desired metal having high thermal conductivity and low electric resistance, examples of which have been described in connection with the first bus bar 46.

The current sensor connection portion 75 is fixed to a lead terminal 52b that protrudes toward the right from the current sensor 18 by screwing a bolt 48 in a state in which the current sensor connection portion 75 is superposed on the lead terminal 52b. Thus, the fourth bus bar 74 and the current sensor 18 are electrically connected.

Furthermore, when an unshown external circuit terminal is bolted to the external connection portion 60b in a state in which the external circuit terminal is superposed on the external connection portion 60b, the external connection portion 60b and the external circuit terminal are electrically connected.

### Lid Member 20

The lid member 20 is obtained by injection molding a material similar to that of the base member 12 into a predetermined shape. The lid member 20 has the shape of a box that is open downward. In the present embodiment, the lid member 20 has a rectangular shape when seen from above so as to correspond to the base member 12. That is, the lid member 20 includes a rectangular upper bottom-wall portion 78 and a peripheral wall portion 80 that protrudes downward from the periphery of the upper bottom-wall portion 78.

As illustrated in FIGS. 1 and 3, opening portions 82a, 82b open in the top-bottom direction are formed in the left-right direction end portions of the lid member 20 by making rectangular shaped cut-outs in the upper bottom-wall portion 78.

### Assembly Process of Circuit Structure 10

Next, one example of an assembly process of the circuit structure 10 will be described. The assembly process of the circuit structure 10 is not limited by the following description.

First, the base member 12 is prepared. Next, two first heat-conducting members 32a, one each of first heat-conducting members 32b, 32c, two second heat-conducting members 34a, and one each of second heat-conducting members 34b, 34c are cut out into predetermined shapes using a known method such as Thomson punching. The first heat-conducting members 32a, 32b, 32c and the second heat-conducting members 34a, 34b, 34c formed in such a manner are respectively arranged inside the first-heat-conducting-member-housing portions 28a, 28b, 28c and the second-heat-conducting-member-housing portions 30a, 30b, 30c. Here, the first heat-conducting members 32a, 32b, 32c are positioned by the bottom surfaces 84 of the first-heat-conducting-member-housing portions 28a, 28b, 28c, which are the contact parts of the base member 12 that come into contact with the heat transfer portions 58, 72, 76, and level differences 85 around the bottom surfaces 84. Furthermore, the second heat-conducting members 34a, 34b, 34c are positioned by the bottom surfaces 86 of the second-heat-conducting-member-housing portions 30a, 30b, 30c, which are the contact parts of the base member 12 that come into contact with an unshown other member that is provided on the outer surface side of the base member 12, and level differences 87 around the bottom surfaces 86. Thus, the transfer of heat can be promoted and insulation can be ensured by the heat transfer portions 58, 72, 76 in a stable fashion.

Subsequently, the first to fourth bus bars 46, 50, 68 74, which constitute energization bus bars, are attached to the relay 14, the fuse 16, and the current sensor 18. For example, first, the bolt insertion hole 62 provided in the first bolt fastening portion 56 of the first bus bar 46 is superposed on the bolt hole 44 provided in the first power terminal 38 of the relay 14, and the heat transfer portion 58 of the first bus bar 46 is brought into contact with the bottom surface of the relay 14. In this state, the first bolt fastening portion 56 of the first bus bar 46 is bolted to the first power terminal 38 of the relay 14. Similarly, the second bolt fastening portion 64 of the second bus bar 50 is bolted to the second power terminal 40 of the relay 14. Thus, the heat transfer portion 58 of the second bus bar 50 is brought into contact with the bottom surface of the relay 14.

Next, the lead terminal 52a protruding toward the left from the fuse 16 is superposed on the fuse connection portion 66 of the second bus bar 50 from below, and the lead terminal 52a and the fuse connection portion 66 are connected using a bolt 48. With regard to the lead terminal 52a protruding toward the right from the fuse 16, the fuse connection portion 69 of the third bus bar 68 is superposed on the lead terminal 52a from above, and the lead terminal 52a and the fuse connection portion 69 are connected using a bolt 48.

With regard to the current sensor connection portion 70 of the third bus bar 68, the lead terminal 52b protruding toward the left from the current sensor 18 is superposed on the current sensor connection portion 70 from below, and the current sensor connection portion 70 and the lead terminal 52b are connected using a bolt 48.

As a result, the relay 14, the fuse 16, and the current sensor 18 are connected in series by the first to fourth bus bars 46, 50, 68, 74, which constitute energization bus bars. The external connection portion 60a, which can be connected to an unshown external circuit terminal, is formed in the left end portion, and the external connection portion 60b, which can be connected to an unshown external circuit terminal, is formed in the right end portion.

A member in which the relay 14, the fuse 16, and the current sensor 18 are connected in series by the first to fourth bus bars 46, 50, 68, 74, which constitute energization bus bars, in such a manner is housed from above into the base member 12 having the first and second heat-conducting members 32a, 32b, 32c, 34a, 34b, 34c arranged thereon. Note that, when the housing is performed, the heat transfer portion 58 of the first bus bar 46, the heat transfer portion 58 of the second bus bar 50, the heat transfer portion 72 of the third bus bar 68, and the heat transfer portion 76 of the fourth bus bar 74 are arranged in a state in which the heat transfer portions 58, 58, 72, 76 are positioned so as to come into contact with the first heat-conducting members 32a, 32a, 32b, 32c from above, respectively.

Finally, the assembly of the circuit structure 10 is completed by covering the base member 12 formed in such a manner from above using the lid member 20. Consequently, the lower surface (i.e., the other surface) of each of the heat transfer portion 58 of the first bus bar 46, the heat transfer portion 58 of the second bus bar 50, the heat transfer portion 72 of the third bus bar 68, and the heat transfer portion 76 of the fourth bus bar 74 is in heat-conductive contact with the base member 12, which is a heat-dissipating body, via a corresponding one of the first heat-conducting members 32a, 32a, 32b, 32c. Here, the parts of the bottom wall 22 of the base member 12 constituting the case that form the bottom surfaces 84 of the first-heat-conducting-member-housing portions 28a, 28b, 28c, which are the contact parts that come into contact with the heat transfer portions 58, 58, 72, 76, are thinner than the vicinity thereof. Furthermore, the upper surface (i.e., the one surface) of each of the heat transfer portion 58 of the first bus bar 46 and the heat transfer portion 58 of the second bus bar 50 is in heat-conductive contact with the bottom surface of the relay 14, which is a heat-generating component. That is, the first heat-conducting members 32a are interposed between contact surfaces of the base member 12 and the relay 14, which is a heat-generating component. Note that the heat transfer portion 72 of the third bus bar 68 is in heat-conductive contact with the fuse 16 and the current sensor 18, which are heat-generating components, via the third bus bar 68 and lead terminals 52a, 52b. Furthermore, the heat transfer portion 76 of the fourth bus bar 74 is in heat-conductive contact with the current sensor 18, which is a heat-generating component, via the fourth bus bar 74 and a lead terminal 52b.

In addition, the heat transfer portion 58 of the first bus bar 46 and the heat transfer portion 58 of the second bus bar 50, which are brought into contact with the bottom surface of the relay 14, are both in heat-conductive contact with the relay 14 on both sides of the relay 14 where the two heat-generating parts A, B are provided. Specifically, the heat transfer portion 58 of the first bus bar 46 and the heat transfer portion 58 of the second bus bar 50 are directly superposed on and brought into contact with substantially the entire bottom surface of the main body 36 of the relay 14, and are in heat-conductive contact with the relay 14 on sides thereof corresponding to the positions inside the case where the heat-generating parts A, B are provided.

Furthermore, as illustrated in FIG. 6, the bottom surfaces 84 of the first-heat-conducting-member-housing portions 28a, which are the contact parts of the base member 12 that come into contact with the heat transfer portions 58 of the first bus bar 46 and the second bus bar 50, come into heat-conductive contact with an unshown other member (for example, a metal housing of a battery pack) that is a heat-dissipating body on the outer surface side of the base member 12 via the second heat-conducting members 34a.

Next, the actions and effects of the present embodiment will be described. According to the present embodiment, the lower surface (i.e., the other surface) of each heat transfer portion 58 is in heat-conductive contact with the base member 12, which is a heat-dissipating body, via a first heat-conducting member 32a, and the upper surface (i.e., the one surface) of each heat transfer portion 58 is superposed on and is in heat-conductive contact with the bottom surface of the relay 14, which is a heat-generating component. By placing the heat transfer portions 58 in direct contact with the bottom surface of the relay 14, which is a heat-generating component, the heat transfer portions 58 can be brought into heat-conductive contact with the base member 12, which is a heat-dissipating body, at a position closest to the relay 14. Thus, heat from a heat-generating component can be dissipated more efficiently compared to a conventional structure in which a bus bar is extended in a direction away from the relay 14 and brought into contact with a heat-dissipating body.

Moreover, since the heat transfer portions 58 can simply be interposed between the relay 14 and the base member 12, the heat transfer portions 58 can be arranged efficiently in an existing space, and the size and cost of the circuit structure 10 can also be reduced. In addition, since the heat transfer portions 58, which come into heat-conductive contact with the relay 14 and the base member 12, can simply be provided so as to be integrated with the first and second bus bars, which are conventional energization bus bars, heat from the heat-generating component can be dissipated in an excellent manner using a compact structure without incurring an increase in the number of components.

Note that, in regard to the fuse 16 and the current sensor 18, which are heat-generating components, the lower surface (i.e., the other surface) of each of the heat transfer portion 72 of the third bus bar 68 and the heat transfer portion 76 of the fourth bus bar 74 is similarly in heat-conductive contact with the base member 12, which is a heat-dissipating body, via a corresponding one of the first heat-conducting members 32b, 32c near the fuse 16 and the current sensor 18. Thus, in regard to the fuse 16 and the current sensor 18 as well, heat from the heat-generating components can be dissipated more efficiently compared to a conventional structure in which a bus bar is extended in a direction away a heat-generating component and brought into contact with a heat-dissipating body outside a case. Furthermore, the lead terminals 52b, 52b of the current sensor 18 are connected to the third bus bar 68 and the fourth bus bar 74, and the heat transfer portion 72 and the heat transfer portion 76 provided in the third bus bar 68 and the fourth bus bar 74 are in heat-conductive contact with the base member 12, which is a heat-dissipating body. Thus, the risk of excessive heat flowing into the current sensor 18 having low heat resistance via the fuse 16 and the external connection portion 60b is reduced or prevented.

Since the bolt insertion holes 62 have the tolerance-absorbing spaces (a₁ and a₂ in FIG. 6) above and below the screw portion 48a of the bolt 48, the heat transfer portions 58 extending from the bottom end portions of the first bolt fastening portion 56 and the second bolt fastening portion 64 can reliably come into contact with the bottom surface of the main body 36 of the relay 14. Thus, the heat transfer portions 58 can be reliably brought into contact with the relay 14, which is a heat-generating component, and heat from the heat-generating component can be dissipated stably.

Since the heat transfer portions 58 are in heat-conductive contact with both of the two heat-generating parts A, B of the relay 14, heat from the entire relay 14 can be dissipated efficiently with few components.

In the present embodiment, the recessed first-heat-conducting-member housing portions 28a, 28b, 28c, which are the contact parts of the bottom wall 22 of the base member 12 that come into contact with the heat transfer portions 58, 58, 72 76, are formed open upward, and are formed to be open above the recessed second-heat-conducting-member-housing portions 30a, 30b, 30c. Consequently, the parts forming the bottom surfaces 84 of the first-heat-conducting-member-housing portions 28a, 28b, 28c, which are the contact parts that come into contact with the heat transfer portions 58, 58, 72, 76, are thinner than the vicinity thereof. Thus, heat can be transferred to the outside via these bottom surfaces 84 more favorably. In a case in which the base member 12 is mounted on a heat-dissipating body (metal housing) having higher heat dissipation performance than the base member 12 does as in the present embodiment, heat from the relay 14, etc., which are heat-generating components, can be dissipated more favorably.

Moreover, the first heat-conducting members 32a, 32a, 32b, 32c are interposed between the heat transfer portions 58, 58, 72 76 and the base member 12, which is a heat-dissipating body. Thus, unintended conduction between the heat transfer portions 58, 58, 72 76 and another member can be reliably avoided while the transfer of heat from the heat transfer portions to the base member 12, which is a heat-dissipating body, is promoted.

The parts of the base member 12 forming the bottom surfaces 84 of the first-heat-conducting-member-housing portions 28a, 28b, 28c, which are the contact parts that come into contact with the heat transfer portions 58, 58, 72 76 of the first to fourth bus bars 46, 50, 68 74, can come into heat-conductive contact with an unshown other member that is a heat-dissipating body on the outer surface side via the second heat-conducting members 34a, 34b, 34c. Thus, unintended conduction between the heat transfer portions 58, 58, 72 76 and the other member can be reliably avoided while the dissipation of heat from the relay 14, the fuse 16, and the current sensor 18 to the other member via the heat transfer portions and the thinned contact parts of the base member 12 that come into contact with the heat transfer portions is even more favorably promoted.

### Other Embodiments

The technique disclosed in the present description is not limited to the embodiment described based on the description above and the drawings, and embodiments such as those described below are also included in the technical scope of the technique disclosed in the present description.

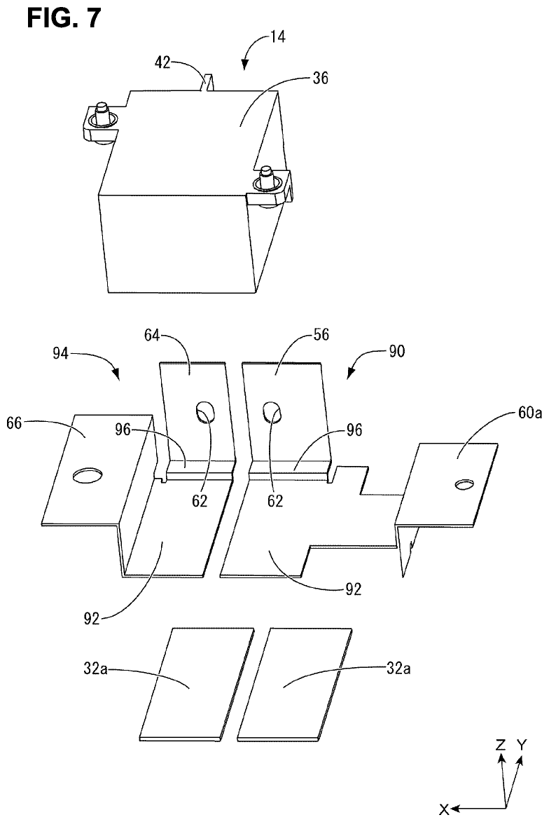

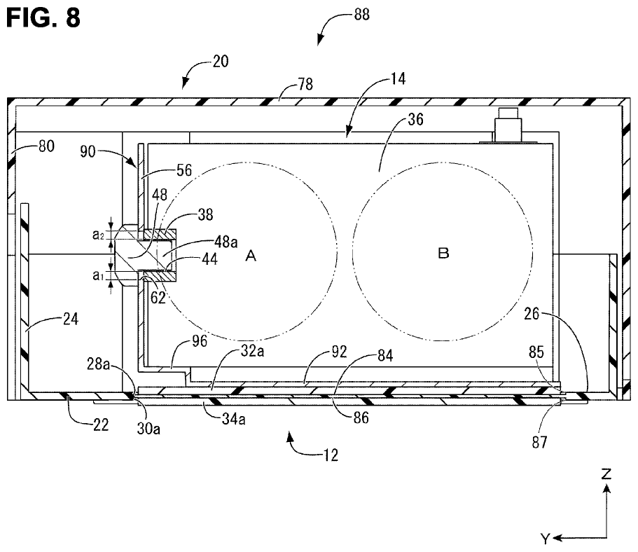

(1) In the circuit structure 10 according to the present disclosure, the heat transfer portion 58 of the first bus bar 46 and the heat transfer portion 58 of the second bus bar 50 are in heat-conductive contact with both of the two heat-generating parts A, B (the contact portion and the excitation coil portion of the relay 14) on the bottom surface of the relay 14. However, there is no limitation to this. For example, as in a circuit structure 88 according to embodiment 2 illustrated in FIGS. 7 and 8, a heat transfer portion 92 of a first bus bar 90 and a heat transfer portion 92 of a second bus bar 94 may be in heat-conductive contact with the heat-generating part A (the contact portion of the relay 14 in the present embodiment), which is one of the two heat-generating parts, and may be separated from the heat-generating part B (the excitation coil portion of the relay 14 in the present embodiment), which is the other one of the two heat-generating parts, on the bottom surface of the relay 14.

For example, there are cases in which the excitation coil portion of the relay 14 generates less heat compared to the contact portion, and the heat generated by the excitation coil portion does not need to be dissipated via the heat transfer portions 92. In such a case, the heat from the contact portion side can be transferred to the heat transfer portions 92 more efficiently by separating the heat transfer portions 92 from the excitation coil portion side as in embodiment 2 illustrated in FIGS. 7 and 8. Thus, heat from the relay 14 can be dissipated more efficiently.

Note that, as the structure for separating the heat transfer portions 92 from the excitation coil portion side for example, any structure can be adopted, such as a structure in which step-wise level-difference portions 96 are provided by bending the first bus bar 90 and the second bus bar 94 as in embodiment 2 illustrated in FIGS. 7 and 8, or a structure in which another member having low heat conductivity is interposed between the excitation coil portion side and the heat transfer portions 92.

(2) Furthermore, the shapes of the first to fourth bus bars 46, 50, 68 74, which constitute energization bus bars, are not limited to those disclosed in embodiment 1, and may be designed, as appropriate, according to arrangement positions of heat-generating components and other components, etc. For example, a shape in which through-holes are formed in the base member, and heat transfer portions directly come into contact with another member (such as a housing of a battery pack, for example) via the through-holes is also included.

(3) Furthermore, if a heat-generating component includes three or more heat-generating parts, a configuration may be adopted such that a heat transfer portion is in heat-conductive contact with all of the heat-generating parts, or such that a heat transfer portion is in contact with only two heat-generating parts.

(4) In addition, desired components that generate heat when energized, such as the relay 14, the fuse 16, and the current sensor 18, are included as heat-generating components. Thus, bus bar shapes may be changed such that heat transfer portions that bring the second bus bar 50, the third bus bar 68, and the fourth bus bar 74, which are energization bus bars that are connected to the fuse 16 and the current sensor 18, into heat-transferable contact with the fuse 16 and the current sensor 18 are provided. Furthermore, as the structure for connecting an energization bus bar to a connection portion of a heat-generating component, any connection structure, such as a bolted structure, may be adopted.

(5) In the circuit structures 10, 88 according to the present disclosure, level differences 87 formed on the outer surface side of the base member 12 constituting the case are used to position the second heat-conducting members 34a, 34b, 34c. However, there is no limitation to this. That is, it suffices as long as a second heat-conducting member is positioned relative to the contact part (bottom surfaces 84, 86) that comes into contact with a heat transfer portion 58 on the outer surface side of the base member 12, and for example, a configuration may be adopted such that the second heat-conducting member is fixedly held by a positioning protrusion or recess that is provided in another member, such as a housing of a battery pack, to which the case including the base member 12 is fixedly attached, and the second heat-conducting member is thus positioned relative to the contact part (bottom surfaces 84, 86) that comes into contact with the heat transfer portion 58 on the outer surface side of the base member 12.

(6) In the circuit structure 10 according to the present disclosure, the heat transfer portion 58 of the first bus bar 46 and the heat transfer portion 58 of the second bus bar 50 are brought into direct contact with and superposed on the bottom surface of the relay 14. However, a heat transfer portion may be brought into contact with the relay 14 via another heat-conducting member.

### Other Matters

There are cases in which current sensors have the problem of low heat resistance. In such a case, the following configuration adopted in the above-described embodiments is effective.

A circuit structure including: terminal portions of a current sensor; energization bus bars that are to be connected to the terminal portions; and a heat transfer portion provided in each of the energization bus bars, wherein the heat transfer portion is in heat-conductive contact with a heat-dissipating body.

Thus, the risk of excessive heat flowing into a current sensor having low heat resistance can be reduced or prevented by heat being transferred from the heat transfer portion to the heat-dissipating body.

### LIST OF REFERENCE NUMERALS

10 Circuit structure (embodiment 1)
12 Base member (case)
14 Relay (heat-generating component)
16 Fuse (heat-generating component)
18 Current sensor (heat-generating component)
20 Lid member (case)
22 Bottom wall
24 Peripheral wall
26 Upper surface
28a-28c First-heat-conducting-member-housing portion
30a-30c Second-heat-conducting-member-housing portion
32a-32c First heat-conducting member
34a-34c Second heat-conducting member
36 Main body
38 First power terminal (connection portion)
40 Second power terminal (connection portion)
42 Insulating plate
44 Bolt hole
46 First bus bar (energization bus bar)
48 Bolt
48a Screw portion
50 Second bus bar (energization bus bar)
52a, 52b Lead terminal (connection portion)
54a, 54b Insertion hole
56 First bolt fastening portion (bolt fastening portion)
58 Heat transfer portion
60a, 60b External connection portion
62 Bolt insertion hole
64 Second bolt fastening portion (bolt fastening portion)
66 Fuse connection portion
68 Third bus bar (energization bus bar)
69 Fuse connection portion
70 Current sensor connection portion
72 Heat transfer portion
74 Fourth bus bar (energization bus bar)
75 Current sensor connection portion
76 Heat transfer portion
78 Upper bottom-wall portion
80 Peripheral wall portion
82a, 82b Opening portion
84 Bottom surface (contact part)
85 Level difference
86 Bottom surface (contact part)
87 Level difference
88 Circuit structure (embodiment 2)
90 First bus bar (energization bus bar)
92 Heat transfer portion
94 Second bus bar (energization bus bar)
96 Level difference portion
a₁, a₂ Tolerance-absorbing space

1. A circuit structure comprising:
a heat-generating component that generates heat when energized;
an energization bus bar that is connected to a connection portion of the heat-generating component; and
a heat transfer portion that is provided in the energization bus bar and that is in heat-conductive contact with a heat-dissipating body,
wherein the heat transfer portion is in heat-conductive contact with the heat-generating component.

2. The circuit structure according to claim 1,
wherein the energization bus bar includes a bolt fastening portion that is bolted to the connection portion, and
a bolt insertion hole provided in the bolt fastening portion includes a tolerance-absorbing space that absorbs the tolerance of the heat-generating component and allows the heat transfer portion to come into contact with the heat-generating component.

3. The circuit structure according to claim 1,
wherein the heat-generating component includes two or more heat-generating parts, and the heat transfer portion is in heat-conductive contact with the heat-generating component on sides thereof corresponding to the two or more heat-generating parts.

4. The circuit structure according to claim 1,
wherein the heat-generating component includes two or more heat-generating parts, and the heat transfer portion is in heat-conductive contact with the heat-generating component on at least one side thereof corresponding to at least one of the two or more heat-generating parts and is separated from the heat-generating component on sides corresponding to the rest of the heat-generating parts.

5. The circuit structure according to claim 1 further comprising
a case that houses the energization bus bar and the heat-generating component,
wherein one surface of the heat transfer portion is in heat-conductive contact with the heat-generating component, and
the other surface of the heat transfer portion is in heat-conductive contact with the case, which is the heat-dissipating body

6. The circuit structure according to claim 5 further comprising
a first heat-conducting member that is interposed between contact surfaces of the heat-generating component and the case,
wherein the first heat-conducting member is positioned relative to a contact part of the case that comes into contact with the heat transfer portion.

7. The circuit structure according to claim 5,
wherein the contact part of the case that comes into contact with the heat transfer portion is in heat-conductive contact with another member that is the heat-dissipating body on an outer surface-side,
the circuit structure further comprises a second heat-conducting member that is interposed between contact surfaces of the other member and the outer surface side of the case, and
the second heat-conducting member is positioned relative to the contact part on the outer surface side of the case.

8. The circuit structure according to claim 6,
wherein the contact part of the case that comes into contact with the heat transfer portion is thinner than the vicinity of the contact part in the case.

9. The circuit structure according to claim 6,
wherein the contact part of the case that comes into contact with the heat transfer portion is thinner than the vicinity of the contact part in the case, and the first heat-conducting member is positioned relative to the contact part by a level difference that is formed at a boundary between the contact part and the vicinity.

10. The circuit structure according to claim 7,
wherein the contact part of the case that comes into contact with the heat transfer portion is thinner than the vicinity of the contact part in the case, and the second heat-conducting member is positioned relative to the contact part by a level difference that is formed at a boundary between the contact part and the vicinity.
